(19) United States
(12) Patent Application Publication
(10) Pub. No.: US 2022/0244307 A1
(43) Pub. Date: Aug. 4, 2022

(54) INTEGRATED CIRCUIT LATCH-UP TEST STRUCTURE

(71) Applicant: CHANGXIN MEMORY TECHNOLOGIES, INC., Hefei (CN)

(72) Inventor: QI'AN XU, Hefei (CN)

(21) Appl. No.: 17/467,213

(22) Filed: Sep. 5, 2021

Related U.S. Application Data
(63) Continuation of application No. PCT/CN2021/104986, filed on Jul. 7, 2021.

(30) Foreign Application Priority Data
Feb. 3, 2021 (CN) 202110149970.8

(51) Int. Cl. G01R 31/28; H01L 27/07

(52) U.S. Cl. CPC G01R 31/2884; H01L 27/0783

(57) ABSTRACT

Embodiment provides an integrated circuit latch-up test structure. The circuit includes: a first P-type heavily doped region, a first N-type heavily doped region, a second P-type heavily doped region, and a second N-type heavily doped region. A first distance is provided between the first P-type heavily doped region and the first N-type heavily doped region, a second distance is provided between the first N-type heavily doped region and the second P-type heavily doped region, and a third distance is provided between the second P-type heavily doped region and the second N-type heavily doped region. The test structure is configured to test electrical parameters of a latch-up effect of an integrated circuit corresponding to the test structure by adjusting at least one of the first distance, the second distance, and the third distance.

### CROSS REFERENCE TO RELATED APPLICATION

This application is a continuation of PCT/CN2021/104986, filed on Jul. 7, 2021, which claims priority to Chinese Patent Application No. 202110149970.8 titled “INTEGRATED CIRCUIT LATCH-UP TEST STRUCTURE” and filed to the State Intellectual Property Office on Feb. 3, 2021, the entire contents of which are incorporated herein by reference.

### TECHNICAL FIELD

The present disclosure relates to the field integrated circuit technologies, and more particularly, to an integrated circuit latch-up test structure.

### BACKGROUND

As a parasitic effect unique to Complementary Metal-Oxide-Semiconductor Transistor (CMOS) technologies, a latch-up effect may seriously cause failure of circuits and even burn out chips. The latch-up effect is produced by an n-p-n-p structure comprising an active region, a P-type substrate and an N-well of an N-channel metal oxide semiconductor (NMOS) and an active region of a P-channel metal oxide semiconductor (PMOS). When one of triodes is positively biased, a positive feedback may be constituted, and latch-up may be formed. As an invisible destructive force, static electricity may have a negative effect on electronic components. Either of the static electricity and related voltage transients may cause the latch-up effect, which is one of primary reasons for the failure of semiconductor devices. The positive feedback may be formed when the latch-up effect occurs. In this case, short circuits of semiconductor components may be formed between power cords and earth wires, which may cause large current, electrical overstress, and even damage to the semiconductor components.

To ensure reliability of the chips, it is required to avoid occurrence of the latch-up effect in integrated circuits. Therefore, in a development stage of the chips, it is necessary to complete the design of the integrated circuits by testing electrical parameters of the integrated circuits in the event of the latch-up effect, to avoid the occurrence of the latch-up effect.

### SUMMARY

The present disclosure provides an integrated circuit latch-up test structure, which includes:

a first P-type heavily doped region, a first N-type heavily doped region, a second P-type heavily doped region, and a second N-type heavily doped region.

The first P-type heavily doped region and the first N-type heavily doped region are both positioned on a P-type substrate, the second P-type heavily doped region and the second N-type heavily doped region both are positioned in an N-well, and the N-well is positioned on the P-type substrate.

A first distance is provided between the first P-type heavily doped region and the first N-type heavily doped region, a second distance is provided between the first N-type heavily doped region and the second P-type heavily doped region, and a third distance is provided between the second P-type heavily doped region and the second N-type heavily doped region.

The test structure is configured to test an electrical parameter of a latch-up effect of an integrated circuit corresponding to the test structure by adjusting at least one of the first distance, the second distance, and the third distance.

The present disclosure also provides an integrated circuit latch-up test structure, which includes:

a first P-type heavily doped region, a first N-type heavily doped region, a second P-type heavily doped region, and a second N-type heavily doped region.

The first P-type heavily doped region is positioned on a P-type substrate, the first N-type heavily doped region is positioned in a first N-well, the second P-type heavily doped region and the second N-type heavily doped region both are positioned in a second N-well, and the first N-well and the second N-well both are positioned on the P-type substrate.

A first distance is provided between the first P-type heavily doped region and the first N-type heavily doped region, a second distance is provided between the first N-type heavily doped region and the second P-type heavily doped region, and a third distance is provided between the second P-type heavily doped region and the second N-type heavily doped region.

The test structure is configured to test an electrical parameter of a latch-up effect of an integrated circuit corresponding to the test structure by adjusting at least one of the first distance, the second distance, and the third distance.

The present disclosure also provides an integrated circuit latch-up test structure, which includes:

a first P-type heavily doped region, a first N-type heavily doped region, a second P-type heavily doped region, and a second N-type heavily doped region.

The first P-type heavily doped region is positioned on a P-type substrate, the first N-type heavily doped region is positioned in a deep N-well, the deep N-well is positioned in a first N-well, the second P-type heavily doped region and the second N-type heavily doped region both are positioned in a second N-well, and the first N-well and the second N-well both are positioned on the P-type substrate.

A first distance is provided between the first P-type heavily doped region and the first N-type heavily doped region, a second distance is provided between the first N-type heavily doped region and the second P-type heavily doped region, and a third distance is provided between the second P-type heavily doped region and the second N-type heavily doped region.

The test structure is configured to test an electrical parameter of a latch-up effect of an integrated circuit corresponding to the test structure by adjusting at least one of the first distance, the second distance, and the third distance.

The present disclosure also provides an integrated circuit latch-up test structure, which includes:

a first N-type heavily doped region, a first P-type heavily doped region, a second N-type heavily doped region, and a second P-type heavily doped region.

The first N-type heavily doped region and the first P-type heavily doped region are both positioned in a deep N-well, the deep N-well is positioned in an N-well, and the N-well is positioned on a P-type substrate.

The second N-type heavily doped region and the second P-type heavily doped region are both positioned in a P-well, and the P-well is positioned in the deep N-well.

A first distance is provided between the first N-type heavily doped region and the first P-type heavily doped region, a second distance is provided between the first P-type heavily doped region and the second N-type heavily doped region, and a third distance is provided between the second N-type heavily doped region and the second P-type heavily doped region.

The test structure is configured to test an electrical parameter of a latch-up effect of an integrated circuit corresponding to the test structure by adjusting at least one of the first distance, the second distance, and the third distance.

The present disclosure also provides an integrated circuit latch-up test structure, which includes:

a first N-type heavily doped region, a first P-type heavily doped region, a second N-type heavily doped region, and a second P-type heavily doped region.

The first N-type heavily doped region is positioned in an N-well, and the N-well is positioned on a P-type substrate.

The first P-type heavily doped region is positioned in a P-well, the P-well is positioned in a deep N-well, and the deep N-well is positioned in the N-well.

The second N-type heavily doped region and the second P-type heavily doped region both are positioned on the P-type substrate.

A first distance is provided between the first N-type heavily doped region and the first P-type heavily doped region, a second distance is provided between the first P-type heavily doped region and the second N-type heavily doped region, and a third distance is provided between the second N-type heavily doped region and the second P-type heavily doped region.

The test structure is configured to test an electrical parameter of a latch-up effect of an integrated circuit corresponding to the test structure by adjusting at least one of the first distance, the second distance, and the third distance.

The present disclosure also provides an integrated circuit latch-up test structure, which includes:

a first N-type heavily doped region, a first P-type heavily doped region, a second N-type heavily doped region, and a second P-type heavily doped region.

The first N-type heavily doped region is positioned in a first N-well, and the first N-well is positioned on a P-type substrate.

The first P-type heavily doped region is positioned in a P-well, the P-well is positioned in a deep N-well, and the deep N-well is positioned in the first N-well.

The second N-type heavily doped region is positioned in a second N-well, and the second N-well is positioned on the P-type substrate.

The second P-type heavily doped region is positioned on the P-type substrate.

A first distance is provided between the first N-type heavily doped region and the first P-type heavily doped region, a second distance is provided between the first P-type heavily doped region and the second N-type heavily doped region, and a third distance is provided between the second N-type heavily doped region and the second P-type heavily doped region.

The test structure is configured to test an electrical parameter of a latch-up effect of an integrated circuit corresponding to the test structure by adjusting at least one of the first distance, the second distance, and the third distance.

The present disclosure also provides an integrated circuit latch-up test structure, which includes:

a first N-type heavily doped region, a first P-type heavily doped region, a second N-type heavily doped region, and a second P-type heavily doped region.

The first N-type heavily doped region is positioned in a first N-well, and the first N-well is positioned on a P-type substrate.

The first P-type heavily doped region is positioned in a P-well, the P-well is positioned in a first deep N-well, and the first deep N-well is positioned in the first N-well.

The second N-type heavily doped region is positioned in a second deep N-well, the second deep N-well is positioned in a second N-well, and the second N-well is positioned on the P-type substrate.

The second P-type heavily doped region is positioned on the P-type substrate.

A first distance is provided between the first N-type heavily doped region and the first P-type heavily doped region, a second distance is provided between the first P-type heavily doped region and the second N-type heavily doped region, and a third distance is provided between the second N-type heavily doped region and the second P-type heavily doped region.

The test structure is configured to test an electrical parameter of a latch-up effect of an integrated circuit corresponding to the test structure by adjusting at least one of the first distance, the second distance, and the third distance.

The present disclosure provides an integrated circuit latch-up test structure. In this test structure, an electrical parameter of a latch-up effect of an integrated circuit corresponding to the integrated circuit latch-up test structure may be tested by adjusting at least one of the first distance, the second distance, and the third distance. In this way, the first distance, the second distance and the third distance in an integrated circuit corresponding to the integrated circuit latch-up test structure may be set by means of the electrical parameter of the latch-up effect and the first distance, the second distance, and the third distance. Thus, occurrence of the latch-up effect can be prevented in a working process of the integrated circuit, and a chip is prevented from being burned out due to the latch-up effect, such that reliability of the chip is improved.

### BRIEF DESCRIPTION OF THE DRAWINGS

FIG. 1 is a schematic diagram showing an application scenario of an integrated circuit latch-up test structure according to the present disclosure;

FIG. 2 is a vertical view of an integrated circuit latch-up test structure according to an embodiment of the present disclosure;

FIG. 3 is a sectional view of an integrated circuit latch-up test structure according to an embodiment of the present disclosure;

FIG. 4 is a schematic connection diagram of the integrated circuit latch-up test structures as shown in FIG. 2 and FIG. 3 when in test;

FIG. 5 is a vertical view of an integrated circuit latch-up test structure according to an embodiment of the present disclosure;

FIG. 6 is a sectional view of an integrated circuit latch-up test structure according to an embodiment of the present disclosure;

FIG. 7 is a schematic connection diagram of the integrated circuit latch-up test structures as shown in FIG. 5 and FIG. 6 when in test;

FIG. 8 is a vertical view of an integrated circuit latch-up test structure according to an embodiment of the present disclosure;

FIG. 9 is a sectional view of an integrated circuit latch-up test structure according to an embodiment of the present disclosure;

FIG. 10 is a schematic connection diagram of the integrated circuit latch-up test structures as shown in FIG. 8 and FIG. 9 when in test;

FIG. 11 is a vertical view of an integrated circuit latch-up test structure according to an embodiment of the present disclosure;

FIG. 12 is a sectional view of an integrated circuit latch-up test structure according to an embodiment of the present disclosure;

FIG. 13 is a schematic connection diagram of the integrated circuit latch-up test structures as shown in FIG. 11 and FIG. 12 when in test;

FIG. 14 is a vertical view of an integrated circuit latch-up test structure according to an embodiment of the present disclosure;

FIG. 15 is a sectional view of an integrated circuit latch-up test structure according to an embodiment of the present disclosure;

FIG. 16 is a schematic connection diagram of the integrated circuit latch-up test structures as shown in FIG. 14 and FIG. 15 when in test;

FIG. 17 is a vertical view of an integrated circuit latch-up test structure according to an embodiment of the present disclosure;

FIG. 18 is a sectional view of an integrated circuit latch-up test structure according to an embodiment of the present disclosure;

FIG. 19 is a schematic connection diagram of the integrated circuit latch-up test structures as shown in FIG. 17 and FIG. 18 when in test;

FIG. 20 is a vertical view of an integrated circuit latch-up test structure according to an embodiment of the present disclosure;

FIG. 21 is a sectional view of an integrated circuit latch-up test structure according to an embodiment of the present disclosure; and

FIG. 22 is a schematic connection diagram of the integrated circuit latch-up test structures as shown in FIG. 20 and FIG. 21 when in test.

### DETAILED DESCRIPTION

A clear and complete description of the technical schemes in the embodiments of the present disclosure is made in conjunction with the accompanying drawings in the embodiments of the present disclosure. Obviously, the embodiments as recited herein are merely a part of embodiments of the present disclosure instead of all embodiments. All other embodiments obtained by a person of ordinary skill in the art based on the embodiments of the present disclosure without creative efforts shall fall within the protection scope of the present disclosure.

It should be explained that in the specification, the claims and the foregoing accompanying drawings of the present disclosure, a term such as “first” or “second” is intended to separate between similar objects but is not intended to describe a particular sequence or precedence order. It is to be understood that data used like this may be interchangeable where appropriate, so that the embodiments of the present disclosure described herein can be implemented in sequences excluding those illustrated or described herein.

Furthermore, terms such as “comprise”, “have” or other variants thereof are intended to cover a non-exclusive “comprise”, for example, processes, methods, systems, products or devices comprising a series of steps or units are not limited to these steps or units listed explicitly, but comprise other steps or units not listed explicitly, or other steps or units inherent to these processes, methods, systems, products or devices.

To ensure reliability of a chip, in a development stage of the chip, it is necessary to complete the design of an integrated circuit by testing electrical parameters of the integrated circuit in the event of a latch-up effect, to avoid the occurrence of the latch-up effect. To solve this problem, the present disclosure provides an integrated circuit latch-up test structure. This test structure includes a first P-type heavily doped region, a first N-type heavily doped region, a second P-type heavily doped region, and a second N-type heavily doped region. A first distance is provided between the first P-type heavily doped region and the first N-type heavily doped region, a second distance is provided between the first N-type heavily doped region and the second P-type heavily doped region, and a third distance is provided between the second P-type heavily doped region and the second N-type heavily doped region. In different integrated circuit latch-up test structures, the first P-type heavily doped regions, the first N-type heavily doped regions, the second P-type heavily doped regions and the second N-type heavily doped regions are arranged on different locations. Electrical parameters of a latch-up effect of an integrated circuit corresponding to the integrated circuit latch-up test structure may be tested by adjusting at least one of the first distance, the second distance, and the third distance. In this way, the first distance, the second distance and the third distance in the integrated circuit corresponding to the integrated circuit latch-up test structure may be set by means of the electrical parameters of the latch-up effect and the first distance, the second distance, and the third distance. Thus, occurrence of the latch-up effect can be prevented in a working process of the integrated circuit, and the chip is prevented from being burned out due to the latch-up effect, such that the reliability of the chip is improved.

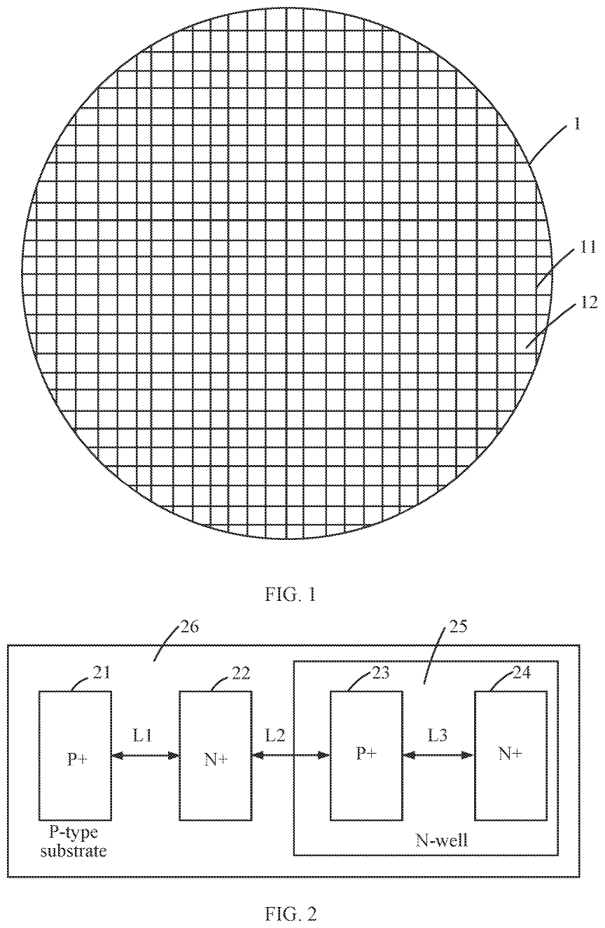

FIG. 1 is a schematic diagram showing an application scenario of an integrated circuit latch-up test structure according to the present disclosure. As shown in FIG. 1, the application scenario of the integrated circuit latch-up test structure provided by the present disclosure relates to a wafer 1 and the integrated circuit latch-up test structure. After the wafer 1 is diced, a plurality of dies 12 and a plurality of scribe lanes 11 are formed. The integrated circuit latch-up test structure may be positioned on the wafer 1. In some embodiments, the integrated circuit latch-up test structure may be positioned in the plurality of scribe lanes 11 or the plurality of dies 12 on the wafer 1. An integrated circuit on the plurality of dies 12 is the same as an equivalent circuit corresponding to the integrated circuit latch-up test structure. Electrical parameters of the latch-up effect of the integrated circuit on the plurality of dies 12 are tested by means of the integrated circuit latch-up test structure. The electrical parameters include a trigger voltage for triggering the latch-up effect, a holding voltage for holding the latch-up effect, a trigger current for triggering the latch-up effect, and a holding current for holding the latch-up effect. The higher the trigger voltage is, the less likely the latch-up effect is triggered; and the higher the holding voltage is, the less likely the latch-up effect is held. Supposing a normal working voltage is 1.1V, a risk of triggering the latch-up effect is higher if the trigger voltage is 1.2V. However, the risk of triggering the latch-up effect is lower if the trigger voltage is 2V. Similarly, the holding voltage has the same principle. It is to be noted that the holding voltage generally is smaller than the trigger voltage. For example, the trigger voltage is 2V, and the holding voltage may be 1.8V.

The integrated circuit latch-up test structure includes a first P-type heavily doped region, a first N-type heavily doped region, a second P-type heavily doped region, and a second N-type heavily doped region. A first distance is provided between the first P-type heavily doped region and the first N-type heavily doped region, a second distance is provided between the first N-type heavily doped region and the second P-type heavily doped region, and a third distance is provided between the second P-type heavily doped region and the second N-type heavily doped region. In different integrated circuit latch-up test structures, the first P-type heavily doped regions, the first N-type heavily doped regions, the second P-type heavily doped regions and the second N-type heavily doped regions are arranged on different locations. The first distance, the second distance and the third distance are associated, to some degree, with the trigger voltage for triggering the latch-up effect, the holding voltage for holding the latch-up effect, the trigger current for triggering the latch-up effect, and the holding current for holding the latch-up effect. The electrical parameters (i.e., the trigger voltage for triggering the latch-up effect, the holding voltage for holding the latch-up effect, the trigger current for triggering the latch-up effect, and the holding current for holding the latch-up effect) of the latch-up effect of the integrated circuit corresponding to the integrated circuit latch-up test structure may be tested by adjusting at least one of the first distance, the second distance, and the third distance. In this way, the first distance, the second distance and the third distance in the integrated circuit on the plurality of dies 12 may be set by means of the electrical parameters of the latch-up effect and the first distance, the second distance, and the third distance. Thus, occurrence of the latch-up effect can be prevented in a working process of the integrated circuit on the plurality of dies 12, and the chip is prevented from being burned out due to the latch-up effect, such that the reliability of the chip is improved.

In some embodiments, various corresponding integrated circuit latch-up test structures may also be designed by changing magnitudes of the first distance, the second distance, and the third distance. The electrical parameters (also referred to as latch-up characteristics) of the latch-up effect of this integrated circuit latch-up test structure may be evaluated based on a transmission line pulse (TLP) test. In this way, related latch-up design rules may be defined based on the latch-up characteristics, such that reliability of the integrated circuit can be ensured.

A structure of the integrated circuit latch-up test structure provided in the present disclosure is described in detail below with reference to some embodiments. FIGS. 2 to 22 illustrate seven types of integrated circuit latch-up test structures in total. In different integrated circuit latch-up test structures, the first P-type heavily doped regions, the first N-type heavily doped regions, the second P-type heavily doped regions and the second N-type heavily doped regions are arranged on different locations. It is to be noted that the P-type heavily doped regions in FIGS. 2 to 22 are abbreviated as P+, and the N-type heavily doped regions are abbreviated as N+.

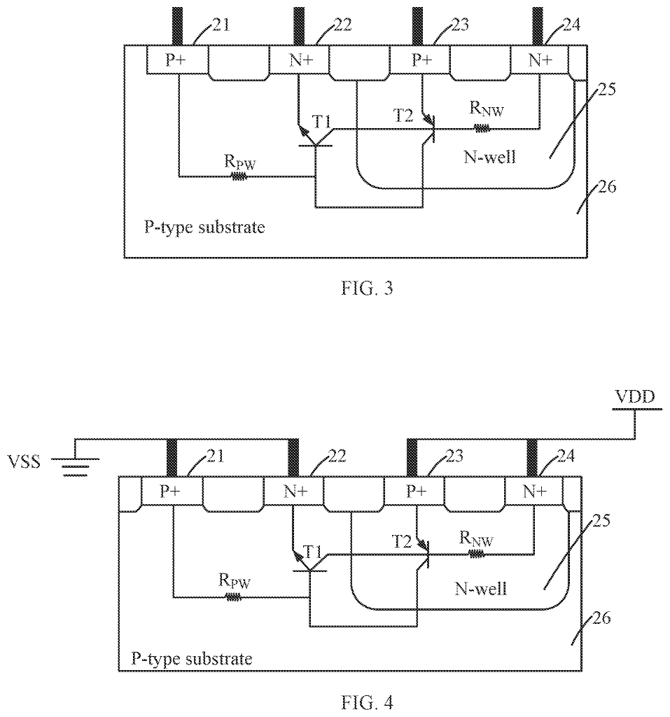

FIG. 2 is a vertical view of an integrated circuit latch-up test structure according to an embodiment of the present disclosure, and FIG. 3 is a sectional view of an integrated circuit latch-up test structure according to an embodiment of the present disclosure. With reference to FIG. 2 and FIG. 3, the integrated circuit latch-up test structure of this embodiment may include: a first P-type heavily doped region 21, a first N-type heavily doped region 22, a second P-type heavily doped region 23, and a second N-type heavily doped region 24.

The first P-type heavily doped region 21 and the first N-type heavily doped region 22 are both positioned on a P-type substrate 26, the second P-type heavily doped region 23 and the second N-type heavily doped region 24 are both positioned in an N-well 25, and the N-well 25 is positioned on the P-type substrate 26.

A first distance L1 is provided between the first P-type heavily doped region 21 and the first N-type heavily doped region 22, a second distance L2 is provided between the first N-type heavily doped region 22 and the second P-type heavily doped region 23, and a third distance L3 is provided between the second P-type heavily doped region 23 and the second N-type heavily doped region 24.

The test structure is configured to test electrical parameters of a latch-up effect of an integrated circuit corresponding to the test structure by adjusting at least one of the first distance L1, the second distance L2, and the third distance L3.

Further, as shown in FIG. 3, the N-well 25, the P-type substrate 26 and the first N-type heavily doped region 22 constitute a first parasitic NPN transistor T1. The second P-type heavily doped region 23, the N-well 25 and the P-type substrate 26 constitute a first parasitic PNP transistor T2.

The P-type substrate 26 has a first parasitic resistor R_{PW}, wherein a first terminal of the first parasitic resistor R_{PW} is connected to the first P-type heavily doped region, and a second terminal of the first parasitic resistor R_{PW} is connected to a base of the first parasitic NPN transistor T1.

The N-well 25 has a second parasitic resistor R_{NW}, wherein a first terminal of the second parasitic resistor R_{NW} is connected to the second N-type heavily doped region 24, and a second terminal of the second parasitic resistor R_{NW} is connected to a base of the first parasitic PNP transistor T2.

Test principles of the integrated circuit latch-up test structure as shown in FIG. 2 and FIG. 3 are described below with reference to FIG. 4. FIG. 4 is a schematic connection diagram of the integrated circuit latch-up test structures as shown in FIG. 2 and FIG. 3 when in test. As shown in FIG. 4, before the test, the first P-type heavily doped region 21 and the first N-type heavily doped region 22 are both connected to a ground terminal VSS, and the second P-type heavily doped region 23 and the second N-type heavily doped region 24 are both connected to a power supply terminal VDD. During the test, a voltage applied to the power supply terminal VDD gradually increases from 0V. For example, the voltage gradually increases from 0V to 5V. An electric current between the power supply terminal VDD and the ground terminal VSS is monitored. When the electric current between the power supply terminal VDD and the ground terminal VSS suddenly increases, it is determined that the latch-up effect occurs at this moment. The first distance L1, the second distance L2 and the third distance L3 are associated, to some degree, with the trigger voltage for triggering the latch-up effect, the holding voltage for holding the latch-up effect, the trigger current for triggering the latch-up effect, and the holding current for holding the latch-up effect. In some embodiments, a corresponding relationship table between the first distance L1, the second distance L2 and the third distance L3 and the trigger voltage for triggering the latch-up effect, the holding voltage for holding the latch-up effect, the trigger current for triggering the latch-up effect, and the holding current for holding the latch-up effect may be obtained. This table may serve as a basis for designing an integrated circuit corresponding to the integrated circuit latch-up test structure as shown in FIG. 2 and FIG. 3, to prevent the occurrence of the latch-up effect in a working process of the integrated circuit corresponding to the integrated circuit latch-up test structure. For example, the corresponding relationship table may be in the form of Table I below.

TABLE I

| | |
|---|---|
| The first set of distances | The trigger voltage for triggering the |
| (including the first | latch-up effect, the holding voltage for |
| distance L1, the second | holding the latch-up effect, the trigger current |
| distance L2, and the | for triggering the latch-up effect, and the |
| third distance L3) | holding current for holding the latch-up |
| | effect |
| The second set of | The trigger voltage for triggering the |
| distances (including | latch-up effect, the holding voltage for |
| the first distance L1, | holding the latch-up effect, the trigger current |
| the second distance | for triggering the latch-up effect, and the |
| L2, and the third | holding current for holding the latch-up |
| distance L3) | effect |
| The third set of distances | The trigger voltage for triggering the |
| (including the first | latch-up effect, the holding voltage for |
| distance L1, the second | holding the latch-up effect, the trigger current |
| distance L2, and the | for triggering the latch-up effect, and the |
| third distance L3) | holding current for holding the latch-up |
| | effect |
| The N^{th} group of | The trigger voltage for triggering the |
| distances (including | latch-up effect, the holding voltage for |
| the first distance L1, the | holding the latch-up effect, the trigger current |
| second distance L2, and | for triggering the latch-up effect, and the |
| the third distance L3) | holding current for holding the latch-up |
| | effect |

Principles of generation of the latch-up effect are described below. In some embodiments, T2 represents a vertical PNP transistor, a base thereof is an N-well, and a gain from the base to a collector may reach up to dozens of times. T1 represents a side-type NPN transistor, a base thereof is a P-type substrate, and a gain from the base to a collector may reach up to dozens of times. R_{NW} represents a parasitic resistor of the N-well, and R_{PW} represents a parasitic resistor of the P-type substrate.

The above four components T1, T2, R_{NW} and R_{PW} constitute a silicon controlled circuit. When there is no external interference or triggering, the two transistors are in an off state. A collector current comprises a reverse leakage current of C-B, and a current gain is very small. In this case, the latch-up effect does not occur. When the collector current of one of the two transistors suddenly increases to a certain value due to external interferences, this may be fed back to the other transistor, such that the two transistors are enabled due to triggering (generally, it is easier to trigger the PNP transistor), and thus a low-impedance path is formed between the power supply terminal VDD and the ground terminal VSS. Afterwards, even though the external interferences disappear, current leakage (i.e., a lock state) between the power supply terminal VDD and the ground terminal VSS may still exist due to positive feedback formed between the two triodes. This results in the latch-up effect.

This embodiment provides an integrated circuit latch-up test structure. In this test structure, electrical parameters of the latch-up effect of the integrated circuit corresponding to the integrated circuit latch-up test structure may be tested by adjusting at least one of the first distance, the second distance, and the third distance. In this way, the first distance, the second distance and the third distance in the integrated circuit corresponding to the integrated circuit latch-up test structure may be set by means of the electrical parameters of the latch-up effect and the first distance, the second distance, and the third distance. Thus, occurrence of the latch-up effect can be prevented in a working process of the integrated circuit, and a chip is prevented from being burned out due to the latch-up effect, such that reliability of the chip is improved.

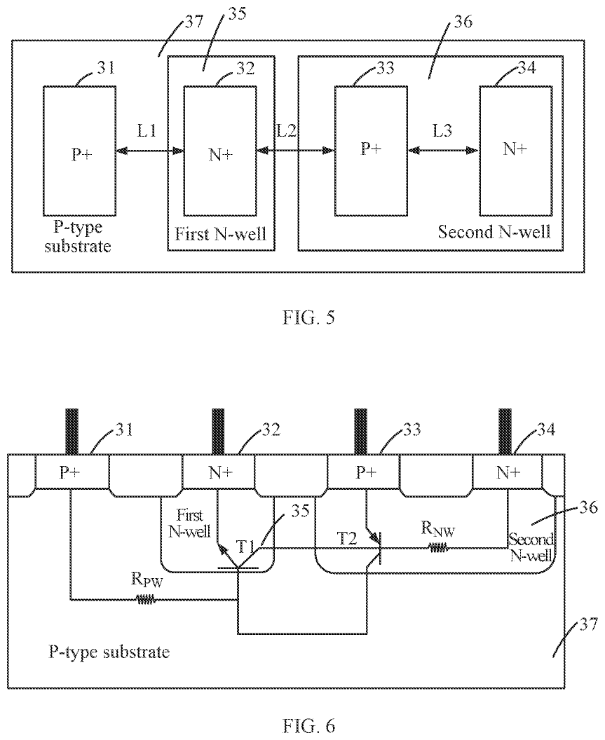

FIG. 5 is a vertical view of an integrated circuit latch-up test structure according to an embodiment of the present disclosure, and FIG. 6 is a sectional view of an integrated circuit latch-up test structure according to an embodiment of the present disclosure. With reference to FIG. 5 and FIG. 6, the integrated circuit latch-up test structure of this embodiment may include: a first P-type heavily doped region 31, a first N-type heavily doped region 32, a second P-type heavily doped region 33, and a second N-type heavily doped region 34.

The first P-type heavily doped region 31 is positioned on a P-type substrate 37, the first N-type heavily doped region 32 is positioned in a first N-well 35, the second P-type heavily doped region 33 and the second N-type heavily doped region 34 both are positioned in a second N-well 36, and the first N-well 35 and the second N-well 36 both are positioned on the P-type substrate 37.

The first distance L1 is provided between the first P-type heavily doped region 31 and the first N-type heavily doped region 32, the second distance L2 is provided between the first N-type heavily doped region 32 and the second P-type heavily doped region 33, and the third distance L3 is provided between the second P-type heavily doped region 33 and the second N-type heavily doped region 34.

The test structure is configured to test the electrical parameters of the latch-up effect of the integrated circuit corresponding to the test structure by adjusting at least one of the first distance L1, the second distance L2, and the third distance L3.

Further, as shown in FIG. 6, the second N-well 36, the P-type substrate 37 and the first N-type heavily doped region 32 constitute the first parasitic NPN transistor T1. The second P-type heavily doped region 33, the second N-well 36 and the P-type substrate 37 constitute the first parasitic PNP transistor T2.

The P-type substrate 37 has a first parasitic resistor R_{PW}, wherein a first terminal of the first parasitic resistor R_{PW} is connected to the first P-type heavily doped region 31, and a second terminal of the first parasitic resistor R_{PW} is connected to a base of the first parasitic NPN transistor T1.

The second N-well 36 has a second parasitic resistor R_{NW}, wherein a first terminal of the second parasitic resistor R_{NW} is connected to the second N-type heavily doped region 34, and a second terminal of the second parasitic resistor R_{NW} is connected to a base of the first parasitic PNP transistor T2.

Test principles of the integrated circuit latch-up test structure as shown in FIG. 5 and FIG. 6 are described below with reference to FIG. 7. FIG. 7 is a schematic connection diagram of the integrated circuit latch-up test structures as shown in FIG. 5 and FIG. 6 when in test. As shown in FIG. 7, before the test, the first P-type heavily doped region 31 and the first N-type heavily doped region 32 are both connected to a ground terminal VSS, and the second P-type heavily doped region 33 and the second N-type heavily doped region 34 are both connected to a power supply terminal VDD. During the test, a voltage applied to the power supply terminal VDD gradually increases from 0V. For example, the voltage gradually increases from 0V to 5V. An electric current between the power supply terminal VDD and the ground terminal VSS is monitored. When the electric current between the power supply terminal VDD and the ground terminal VSS suddenly increases, it is determined that the latch-up effect occurs at this moment. The first distance L1, the second distance L2 and the third distance L3 are associated, to some degree, with the trigger voltage for triggering the latch-up effect, the holding voltage for holding the latch-up effect, the trigger current for triggering the latch-up effect, and the holding current for holding the latch-up effect. In some embodiments, a corresponding relationship table between the first distance L1, the second distance L2 and the third distance L3 and the trigger voltage for triggering the latch-up effect, the holding voltage for holding the latch-up effect, the trigger current for triggering the latch-up effect, and the holding current for holding the latch-up effect may be obtained. This table may serve as a basis for designing an integrated circuit corresponding to the integrated circuit latch-up test structure as shown in FIG. 5 and FIG. 6, to prevent the occurrence of the latch-up effect in a working process of the integrated circuit corresponding to the integrated circuit latch-up test structure. For example, the corresponding relationship table may be in the form of Table I above.

Principles of generation of the latch-up effect are described below. In some embodiments, T2 represents a vertical PNP transistor, a base thereof is an N-well, and a gain from the base to a collector may reach up to hundreds of times. T1 represents a side-type NPN transistor, a base thereof is a P-type substrate, and a gain from the base to a collector may reach up to dozens of times. R_{NW} represents a parasitic resistor of the second N-well, and R_{PW} represents a parasitic resistor of the P-type substrate.

The above four components T1, T2, R_{NW} and R_{PW} constitute a silicon controlled circuit. When there is no external interference or triggering, the two transistors are in an off state. A collector current comprises a reverse leakage current of C-B, and a current gain is very small. In this case, the latch-up effect does not occur. When the collector current of one of the two transistors suddenly increases to a certain value due to external interferences, this may be fed back to the other transistor, such that the two transistors are enabled due to triggering (generally, it is easier to trigger the PNP transistor), and thus a low-impedance path is formed between the power supply terminal VDD and the ground terminal VSS. Afterwards, even though the external interferences disappear, current leakage (i.e., a lock state) between the power supply terminal VDD and the ground terminal VSS may still exist due to positive feedback formed between the two triodes. This results in the latch-up effect.

This embodiment provides an integrated circuit latch-up test structure. In this test structure, electrical parameters of the latch-up effect of an integrated circuit corresponding to the integrated circuit latch-up test structure may be tested by adjusting at least one of the first distance, the second distance, and the third distance. In this way, the first distance, the second distance and the third distance in the integrated circuit corresponding to the integrated circuit latch-up test structure may be set by means of the electrical parameters of the latch-up effect and the first distance, the second distance, and the third distance. Thus, occurrence of the latch-up effect can be prevented in a working process of the integrated circuit, and a chip is prevented from being burned out due to the latch-up effect, such that reliability of the chip is improved.

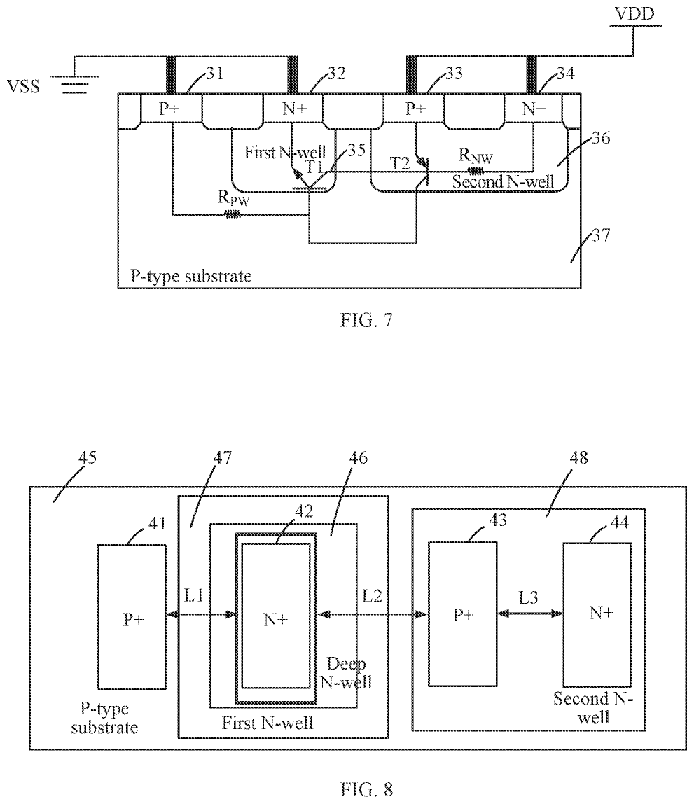

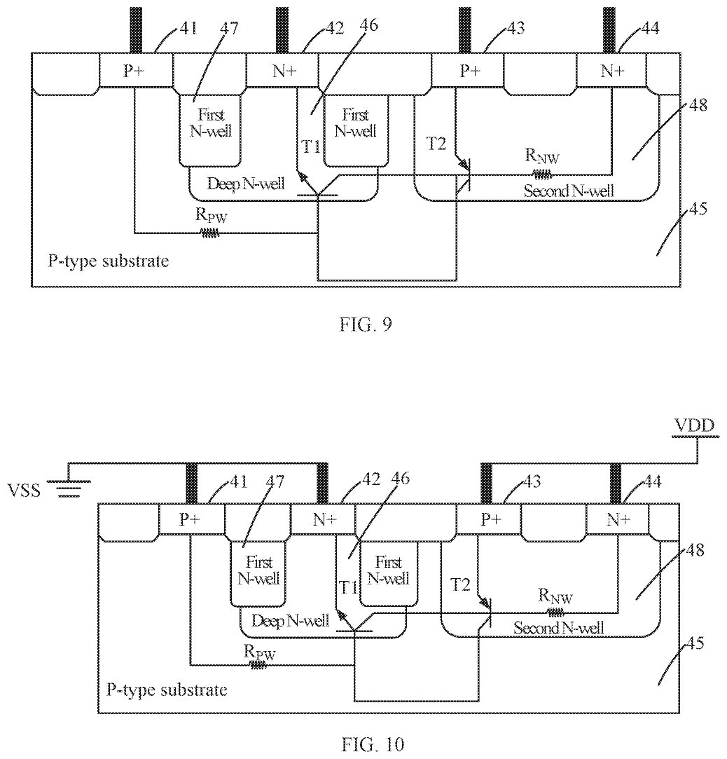

FIG. 8 is a vertical view of an integrated circuit latch-up test structure according to an embodiment of the present disclosure, and FIG. 9 is a sectional view of an integrated circuit latch-up test structure according to an embodiment of the present disclosure. With reference to FIG. 8 and FIG. 9, the integrated circuit latch-up test structure of this embodiment may include: a first P-type heavily doped region 41, a first N-type heavily doped region 42, a second P-type heavily doped region 43, and a second N-type heavily doped region 44.

The first P-type heavily doped region 41 is positioned on a P-type substrate 45, the first N-type heavily doped region 42 is positioned in a deep N-well 46, the deep N-well 46 is positioned in a first N-well 47, the second P-type heavily doped region 43 and the second N-type heavily doped region 44 both are positioned in a second N-well 48, and the first N-well 47 and the second N-well 48 both are positioned on the P-type substrate 45.

The first distance L1 is provided between the first P-type heavily doped region 41 and the first N-type heavily doped region 42, the second distance L2 is provided between the first N-type heavily doped region 42 and the second P-type heavily doped region 43, and the third distance L3 is provided between the second P-type heavily doped region 43 and the second N-type heavily doped region 44.

The test structure is configured to test the electrical parameters of the latch-up effect of the integrated circuit corresponding to the test structure by adjusting at least one of the first distance L1, the second distance L2, and the third distance L3.

Further, as shown in FIG. 9, the second N-well 48, the P-type substrate 45 and the deep N-well 46 constitute the first parasitic NPN transistor T1. The second P-type heavily doped region 43, the second N-well 48 and the P-type substrate 45 constitute the first parasitic PNP transistor T2.

The P-type substrate 45 has a first parasitic resistor R_{PW}, wherein a first terminal of the first parasitic resistor R_{PW} is connected to the first P-type heavily doped region 41, and a second terminal of the first parasitic resistor R_{PW} is connected to an emitter of the first parasitic NPN transistor T1.

The second N-well 48 has a second parasitic resistor R_{NW}, wherein a first terminal of the second parasitic resistor R_{NW} is connected to the second N-type heavily doped region 44, and a second terminal of the second parasitic resistor R_{NW} is connected to a base of the first parasitic PNP transistor T2.

Test principles of the integrated circuit latch-up test structure as shown in FIG. 8 and FIG. 9 are described below with reference to FIG. 10. FIG. 10 is a schematic connection diagram of the integrated circuit latch-up test structures as shown in FIG. 8 and FIG. 9 when in test. As shown in FIG. 10, before the test, the first P-type heavily doped region 41 and the first N-type heavily doped region 42 are both connected to a ground terminal VSS, and the second P-type heavily doped region 43 and the second N-type heavily doped region 44 are both connected to a power supply terminal VDD. During the test, a voltage applied to the power supply terminal VDD gradually increases from 0V. For example, the voltage gradually increases from 0V to 5V. An electric current between the power supply terminal VDD and the ground terminal VSS is monitored. When the electric current between the power supply terminal VDD and the ground terminal VSS suddenly increases, it is determined that the latch-up effect occurs at this moment. The first distance L1, the second distance L2 and the third distance L3 are associated, to some degree, with the trigger voltage for triggering the latch-up effect, the holding voltage for holding the latch-up effect, the trigger current for triggering the latch-up effect, and the holding current for holding the latch-up effect. In some embodiments, a corresponding relationship table between the first distance L1, the second distance L2 and the third distance L3 and the trigger voltage for triggering the latch-up effect, the holding voltage for holding the latch-up effect, the trigger current for triggering the latch-up effect, and the holding current for holding the latch-up effect may be obtained. This table may serve as a basis for designing an integrated circuit corresponding to the integrated circuit latch-up test structure as shown in FIG. 8 and FIG. 9, to prevent the occurrence of the latch-up effect in a working process of the integrated circuit corresponding to the integrated circuit latch-up test structure. For example, the corresponding relationship table may be in the form of Table I above.

Principles of generation of the latch-up effect are described below. In some embodiments, T2 represents a vertical PNP transistor, a base thereof is an N-well, and a gain from the base to a collector may reach up to hundreds of times. T1 represents a side-type NPN transistor, a base thereof is a P-type substrate, and a gain from the base to a collector may reach up to dozens of times. R_{NW} represents a parasitic resistor of the second N-well, and R_{PW} represents a parasitic resistor of the P-type substrate.

The above four components T1, T2, R_{NW} and R_{PW} constitute a silicon controlled circuit. When there is no external interference or triggering, the two transistors are in an off state. A collector current comprises a reverse leakage current of C-B, and a current gain is very small. In this case, the latch-up effect does not occur. When the collector current of one of the two transistors suddenly increases to a certain value due to external interferences, this may be fed back to the other transistor, such that the two transistors are enabled due to triggering (generally, it is easier to trigger the PNP transistor), and thus a low-impedance path is formed between the power supply terminal VDD and the ground terminal VSS. Afterwards, even though the external interferences disappear, current leakage (i.e., a lock state) between the power supply terminal VDD and the ground terminal VSS may still exist due to positive feedback formed between the two triodes. This results in the latch-up effect.

This embodiment provides an integrated circuit latch-up test structure. In this test structure, electrical parameters of the latch-up effect of an integrated circuit corresponding to the integrated circuit latch-up test structure may be tested by adjusting at least one of the first distance, the second distance, and the third distance. In this way, the first distance, the second distance and the third distance in the integrated circuit corresponding to the integrated circuit latch-up test structure may be set by means of the electrical parameters of the latch-up effect and the first distance, the second distance, and the third distance. Thus, occurrence of the latch-up effect can be prevented in a working process of the integrated circuit, and a chip is prevented from being burned out due to the latch-up effect, such that reliability of the chip is improved.

FIG. 11 is a vertical view of an integrated circuit latch-up test structure according to an embodiment of the present disclosure, and FIG. 12 is a sectional view of an integrated circuit latch-up test structure according to an embodiment of the present disclosure. With reference to FIG. 11 and FIG. 12, the integrated circuit latch-up test structure of this embodiment may include: a first N-type heavily doped region 51, a first P-type heavily doped region 52, a second N-type heavily doped region 53, and a second P-type heavily doped region 54.

The first N-type heavily doped region 51 and the first P-type heavily doped region 52 are both positioned in a deep N-well 55, the deep N-well 55 is positioned in an N-well 56, and the N-well 56 is positioned on a P-type substrate 57. The second N-type heavily doped region 53 and the second P-type heavily doped region 54 are both positioned in a P-well 58, and the P-well 58 is positioned in a deep N-well 55.

The first distance L1 is provided between the first N-type heavily doped region 51 and the first P-type heavily doped region 52, the second distance L2 is provided between the first P-type heavily doped region 52 and the second N-type heavily doped region 53, and the third distance L3 is provided between the second N-type heavily doped region 53 and the second P-type heavily doped region 54.

The test structure is configured to test the electrical parameters of the latch-up effect of the integrated circuit corresponding to the test structure by adjusting at least one of the first distance L1, the second distance L2, and the third distance L3.

Further, as shown in FIG. 12, the first P-type heavily doped region 52, the deep N-well 55 and the second P-type heavily doped region 54 constitute the first parasitic PNP transistor T1. The first N-type heavily doped region 51, the P-type substrate 57 and the deep N-well 55 constitute the first parasitic NPN transistor T2.

The deep N-well 55 has a first parasitic resistor R_{DNW}, wherein a first terminal of the first parasitic resistor R_{DNW} is connected to the first N-type heavily doped region, and a second terminal of the first parasitic resistor R_{DNW} is connected to a base of the first parasitic PNP transistor T1.

The P-well 58 has a second parasitic resistor R_{PW}, wherein a first terminal of the second parasitic resistor R_{PW} is connected to the second P-type heavily doped region 54, and a second terminal of the second parasitic resistor R_{PW} is connected to a base of the first parasitic NPN transistor T2 and a collector of the first parasitic PNP transistor T1.

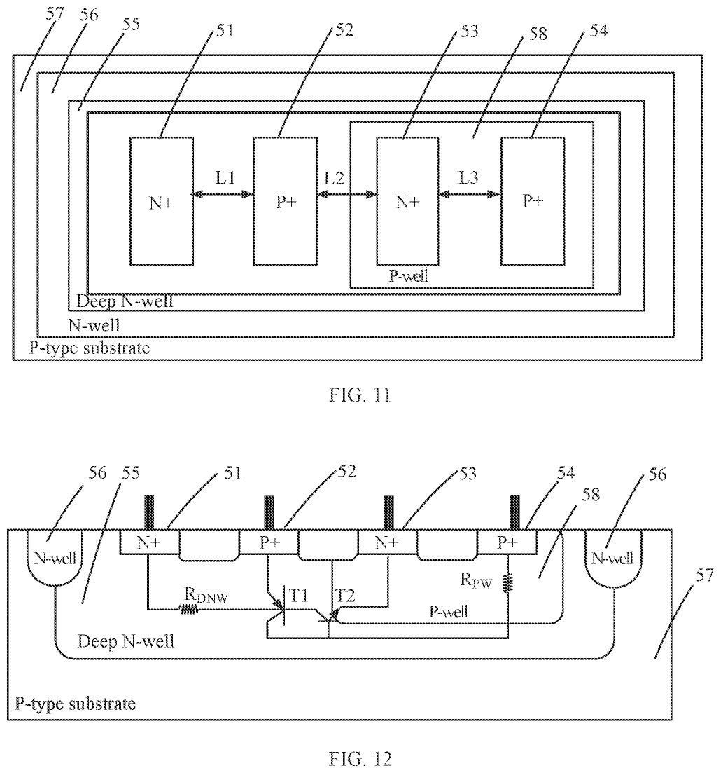

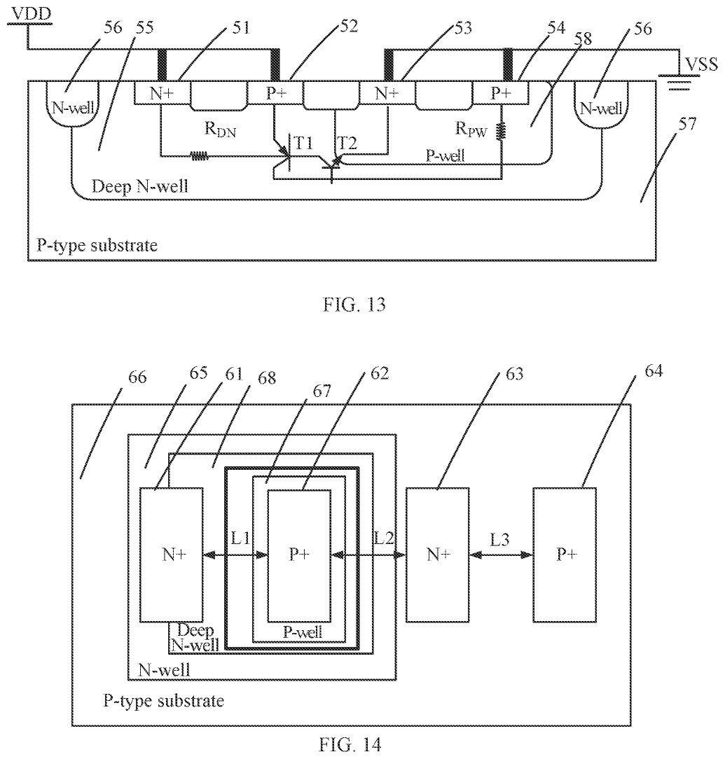

Test principles of the integrated circuit latch-up test structure as shown in FIG. 11 and FIG. 12 are described below with reference to FIG. 13. FIG. 13 is a schematic connection diagram of the integrated circuit latch-up test structures as shown in FIG. 11 and FIG. 12 when in test. As shown in FIG. 13, before the test, the first P-type heavily doped region 52 and the first N-type heavily doped region 51 are both connected to a power supply terminal VDD, and the second P-type heavily doped region 43 and the second N-type heavily doped region 44 are both connected to a ground terminal VSS. During the test, a voltage applied to the power supply terminal VDD gradually increases from 0V. For example, the voltage gradually increases from 0V to 5V. An electric current between the power supply terminal VDD and the ground terminal VSS is monitored. When the electric current between the power supply terminal VDD and the ground terminal VSS suddenly increases, it is determined that the latch-up effect occurs at this moment. The first distance L1, the second distance L2 and the third distance L3 are associated, to some degree, with the trigger voltage for triggering the latch-up effect, the holding voltage for holding the latch-up effect, the trigger current for triggering the latch-up effect, and the holding current for holding the latch-up effect. In some embodiments, a corresponding relationship table between the first distance L1, the second distance L2 and the third distance L3 and the trigger voltage for triggering the latch-up effect, the holding voltage for holding the latch-up effect, the trigger current for triggering the latch-up effect, and the holding current for holding the latch-up effect may be obtained. This table may serve as a basis for designing an integrated circuit corresponding to the integrated circuit latch-up test structure as shown in FIG. 11 and FIG. 12, to prevent the occurrence of the latch-up effect in a working process of the integrated circuit corresponding to the integrated circuit latch-up test structure. For example, the corresponding relationship table may be in the form of Table I above.

Principles of generation of the latch-up effect are described below. In some embodiments, T1 represents a vertical PNP transistor, a base thereof is an N-well, and a gain from the base to a collector may reach up to hundreds of times. T2 represents a side-type NPN transistor, a base thereof is a P-type substrate, and a gain from the base to a collector may reach up to dozens of times. R_{DNW} represents a parasitic resistor of the deep N-well, and R_{PW} represents a parasitic resistor of the P-well.

The above four components T1, T2, R_{DNW} and R_{PW} constitute a silicon controlled circuit. When there is no external interference or triggering, the two transistors are in an off state. A collector current comprises a reverse leakage current of C-B, and a current gain is very small. In this case, the latch-up effect does not occur. When the collector current of one of the two transistors suddenly increases to a certain value due to external interferences, this may be fed back to the other transistor, such that the two transistors are enabled due to triggering (generally, it is easier to trigger the PNP transistor), and thus a low-impedance path is formed between the power supply terminal VDD and the ground terminal VSS. Afterwards, even though the external interferences disappear, current leakage (i.e., a lock state) between the power supply terminal VDD and the ground terminal VSS may still exist due to positive feedback formed between the two triodes. This results in the latch-up effect.

This embodiment provides an integrated circuit latch-up test structure. In this test structure, electrical parameters of the latch-up effect of an integrated circuit corresponding to the integrated circuit latch-up test structure may be tested by adjusting at least one of the first distance, the second distance, and the third distance. In this way, the first distance, the second distance and the third distance in the integrated circuit corresponding to the integrated circuit latch-up test structure may be set by means of the electrical parameters of the latch-up effect and the first distance, the second distance, and the third distance. Thus, occurrence of the latch-up effect can be prevented in a working process of the integrated circuit, and a chip is prevented from being burned out due to the latch-up effect, such that reliability of the chip is improved.

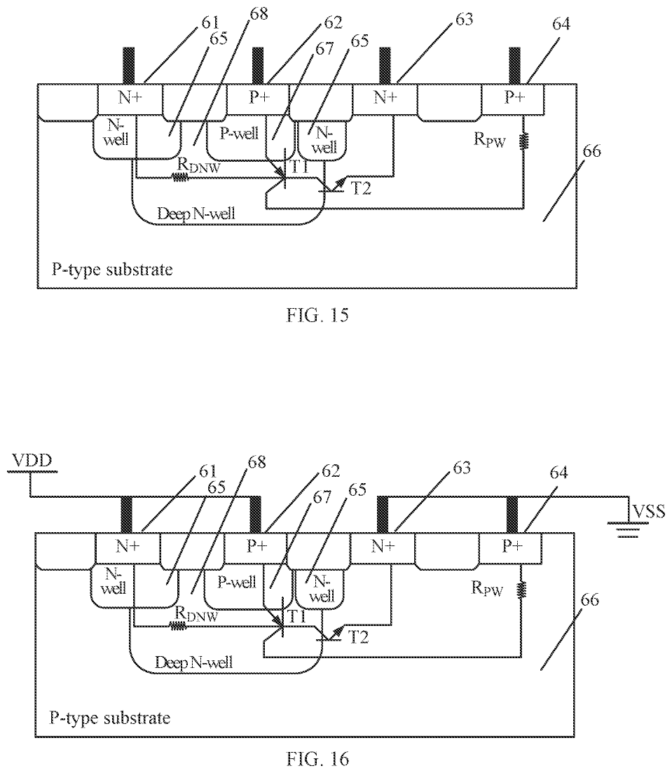

FIG. 14 is a vertical view of an integrated circuit latch-up test structure according to an embodiment of the present disclosure, and FIG. 15 is a sectional view of an integrated circuit latch-up test structure according to an embodiment of the present disclosure. With reference to FIG. 14 and FIG. 15, the integrated circuit latch-up test structure of this embodiment may include: a first N-type heavily doped region 61, a first P-type heavily doped region 62, a second N-type heavily doped region 63, and a second P-type heavily doped region 64.

The first N-type heavily doped region 61 is positioned in an N-well 65, and the N-well 65 is positioned on a P-type substrate 66. The first P-type heavily doped region 62 is positioned in a P-well 67, the P-well 67 is positioned in a deep N-well 68, and the deep N-well 68 is positioned in the N-well 65. The second N-type heavily doped region 63 and the second P-type heavily doped region 64 both are positioned on the P-type substrate 66.

The first distance L1 is provided between the first N-type heavily doped region 61 and the first P-type heavily doped region 62, the second distance L2 is provided between the first P-type heavily doped region 62 and the second N-type heavily doped region 63, and the third distance L3 is provided between the second N-type heavily doped region 63 and the second P-type heavily doped region 64.

The test structure is configured to test the electrical parameters of the latch-up effect of the integrated circuit corresponding to the test structure by adjusting at least one of the first distance L1, the second distance L2, and the third distance L3.

Further, as shown in FIG. 15, the P-well 67, the deep N-well 68 and the P-type substrate 66 constitute the first parasitic PNP transistor T1. The deep N-well 68, the P-type substrate 66 and the second N-type heavily doped region 63 constitute the first parasitic NPN transistor T2.

The deep N-well 68 has a first parasitic resistor R_{DNW}, wherein a first terminal of the first parasitic resistor R_{DNW} is connected to the first N-type heavily doped region 61, and a second terminal of the first parasitic resistor R_{DNW} is connected to a base of the first parasitic PNP transistor T1.

The P-type substrate 66 has a second parasitic resistor R_{PW}, wherein a first terminal of the second parasitic resistor R_{PW} is connected to the second P-type heavily doped region 64, and a second terminal of the second parasitic resistor R_{PW} is connected to a base of the first parasitic NPN transistor T2 and a collector of the first parasitic PNP transistor T1.

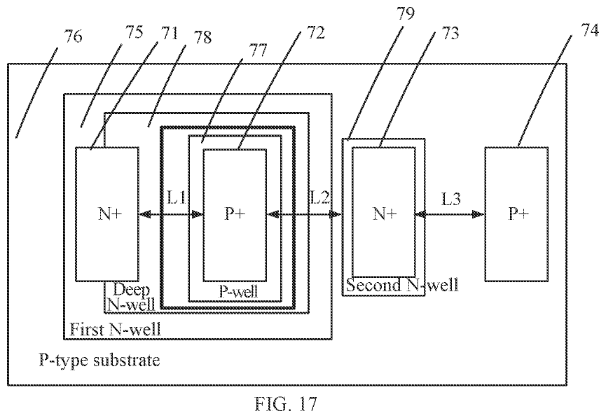

Test principles of the integrated circuit latch-up test structure as shown in FIG. 14 and FIG. 15 are described below with reference to FIG. 16. FIG. 16 is a schematic connection diagram of the integrated circuit latch-up test structures as shown in FIG. 14 and FIG. 15 when in test. As shown in FIG. 16, before the test, the first P-type heavily doped region 62 and the first N-type heavily doped region 61 are both connected to a power supply terminal VDD, and the second P-type heavily doped region 64 and the second N-type heavily doped region 63 are both connected to a ground terminal VSS. During the test, a voltage applied to the power supply terminal VDD gradually increases from 0V. For example, the voltage gradually increases from 0V to 5V. An electric current between the power supply terminal VDD and the ground terminal VSS is monitored. When the electric current between the power supply terminal VDD and the ground terminal VSS suddenly increases, it is determined that the latch-up effect occurs at this moment. The first distance L1, the second distance L2 and the third distance L3 are associated, to some degree, with the trigger voltage for triggering the latch-up effect, the holding voltage for holding the latch-up effect, the trigger current for triggering the latch-up effect, and the holding current for holding the latch-up effect. In some embodiments, a corresponding relationship table between the first distance L1, the second distance L2 and the third distance L3 and the trigger voltage for triggering the latch-up effect, the holding voltage for holding the latch-up effect, the trigger current for triggering the latch-up effect, and the holding current for holding the latch-up effect may be obtained. This table may serve as a basis for designing an integrated circuit corresponding to the integrated circuit latch-up test structure as shown in FIG. 14 and FIG. 15, to prevent the occurrence of the latch-up effect in a working process of the integrated circuit corresponding to the integrated circuit latch-up test structure. For example, the corresponding relationship table may be in the form of Table I above.

Principles of generation of the latch-up effect are described below. In some embodiments, T1 represents a vertical PNP transistor, a base thereof is an N-well, and a gain from the base to a collector may reach up to hundreds of times. T2 represents a side-type NPN transistor, a base thereof is a P-type substrate, and a gain from the base to a collector may reach up to dozens of times. R_{DNW} represents a parasitic resistor of the deep N-well, and R_{PW} represents a parasitic resistor of the P-type substrate.

The above four components T1, T2, R_{DNW} and R_{PW} constitute a silicon controlled circuit. When there is no external interference or triggering, the two transistors are in an off state. A collector current comprises a reverse leakage current of C-B, and a current gain is very small. In this case, the latch-up effect does not occur. When the collector current of one of the two transistors suddenly increases to a certain value due to external interferences, this may be fed back to the other transistor, such that the two transistors are enabled due to triggering (generally, it is easier to trigger the PNP transistor), and thus a low-impedance path is formed between the power supply terminal VDD and the ground terminal VSS. Afterwards, even though the external interferences disappear, current leakage (i.e., a lock state) between the power supply terminal VDD and the ground terminal VSS may still exist due to positive feedback formed between the two triodes. This results in the latch-up effect.

This embodiment provides an integrated circuit latch-up test structure. In this test structure, electrical parameters of the latch-up effect of an integrated circuit corresponding to the integrated circuit latch-up test structure may be tested by adjusting at least one of the first distance, the second distance, and the third distance. In this way, the first distance, the second distance and the third distance in the integrated circuit corresponding to the integrated circuit latch-up test structure may be set by means of the electrical parameters of the latch-up effect and the first distance, the second distance, and the third distance. Thus, occurrence of the latch-up effect can be prevented in a working process of the integrated circuit, and a chip is prevented from being burned out due to the latch-up effect, such that reliability of the chip is improved.

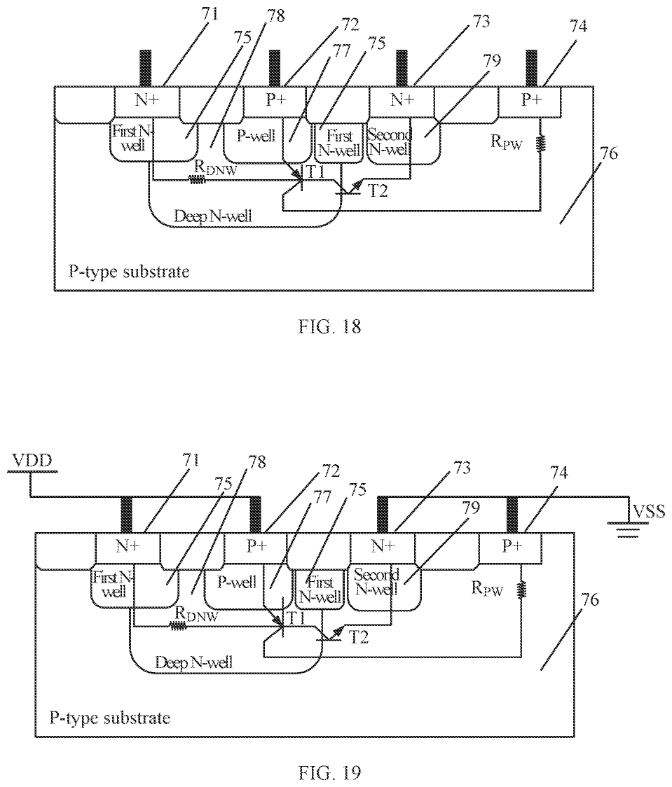

FIG. 17 is a vertical view of an integrated circuit latch-up test structure according to an embodiment of the present disclosure, and FIG. 18 is a sectional view of an integrated circuit latch-up test structure according to an embodiment of the present disclosure. With reference to FIG. 17 and FIG. 18, the integrated circuit latch-up test structure of this embodiment may include: a first N-type heavily doped region 71, a first P-type heavily doped region 72, a second N-type heavily doped region 73, and a second P-type heavily doped region 74.

The first N-type heavily doped region 71 is positioned in a first N-well 75, and the first N-well 75 is positioned on a P-type substrate 76. The first P-type heavily doped region 72 is positioned in a P-well 77, the P-well 77 is positioned in a deep N-well 78, and the deep N-well 78 is positioned in the first N-well 75. The second N-type heavily doped region 73 is positioned in a second N-well 79, and the second N-well 79 is positioned on a P-type substrate 76. The second P-type heavily doped region 74 is positioned on the P-type substrate 76.

The first distance L1 is provided between the first N-type heavily doped region 71 and the first P-type heavily doped region 72, the second distance L2 is provided between the first P-type heavily doped region 72 and the second N-type heavily doped region 73, and the third distance L3 is provided between the second N-type heavily doped region 73 and the second P-type heavily doped region 74.

The test structure is configured to test the electrical parameters of the latch-up effect of the integrated circuit corresponding to the test structure by adjusting at least one of the first distance L1, the second distance L2, and the third distance L3.

Further, as shown in FIG. 18, the P-well 77, the deep N-well 78 and the P-type substrate 76 constitute the first parasitic PNP transistor T1. The deep N-well 78, the P-type substrate 76 and the second N-well 79 constitute the first parasitic NPN transistor T2.

The deep N-well 78 has a first parasitic resistor R_{DNW}, wherein a first terminal of the first parasitic resistor R_{DNW} is connected to the first N-type heavily doped region 71, and a second terminal of the first parasitic resistor R_{DNW} is connected to a base of the first parasitic PNP transistor T1.

The P-type substrate 76 has a second parasitic resistor R_{PW}, wherein a first terminal of the second parasitic resistor R_{PW} is connected to the second P-type heavily doped region 74, and a second terminal of the second parasitic resistor R_{PW} is connected to a base of the first parasitic NPN transistor T2 and a collector of the first parasitic PNP transistor T1.

Test principles of the integrated circuit latch-up test structure as shown in FIG. 17 and FIG. 18 are described below with reference to FIG. 19. FIG. 19 is a schematic connection diagram of the integrated circuit latch-up test structures as shown in FIG. 17 and FIG. 18 when in test. As shown in FIG. 19, before the test, the first P-type heavily doped region 72 and the first N-type heavily doped region 71 are both connected to a power supply terminal VDD, and the second P-type heavily doped region 74 and the second N-type heavily doped region 73 are both connected to a ground terminal VSS. During the test, a voltage applied to the power supply terminal VDD gradually increases from 0V. For example, the voltage gradually increases from 0V to 5V. An electric current between the power supply terminal VDD and the ground terminal VSS is monitored. When the electric current between the power supply terminal VDD and the ground terminal VSS suddenly increases, it is determined that the latch-up effect occurs at this moment. The first distance L1, the second distance L2 and the third distance L3 are associated, to some degree, with the trigger voltage for triggering the latch-up effect, the holding voltage for holding the latch-up effect, the trigger current for triggering the latch-up effect, and the holding current for holding the latch-up effect. In some embodiments, a corresponding relationship table between the first distance L1, the second distance L2 and the third distance L3 and the trigger voltage for triggering the latch-up effect, the holding voltage for holding the latch-up effect, the trigger current for triggering the latch-up effect, and the holding current for holding the latch-up effect may be obtained. This table may serve as a basis for designing an integrated circuit corresponding to the integrated circuit latch-up test structure as shown in FIG. 17 and FIG. 18, to prevent the occurrence of the latch-up effect in a working process of the integrated circuit corresponding to the integrated circuit latch-up test structure. For example, the corresponding relationship table may be in the form of Table I above.

Principles of generation of the latch-up effect are described below. In some embodiments, T1 represents a vertical PNP transistor, a base thereof is an N-well, and a gain from the base to a collector may reach up to hundreds of times. T2 represents a side-type NPN transistor, a base thereof is a P-type substrate, and a gain from the base to a collector may reach up to dozens of times. R_{DNW} represents a parasitic resistor of the deep N-well, and R_{PW} represents a parasitic resistor of the P-type substrate.

The above four components T1, T2, R_{DNW} and R_{PW} constitute a silicon controlled circuit. When there is no external interference or triggering, the two transistors are in an off state. A collector current comprises a reverse leakage current of C-B, and a current gain is very small. In this case, the latch-up effect does not occur. When the collector current of one of the two transistors suddenly increases to a certain value due to external interferences, this may be fed back to the other transistor, such that the two transistors are enabled due to triggering (generally, it is easier to trigger the PNP transistor), and thus a low-impedance path is formed between the power supply terminal VDD and the ground terminal VSS. Afterwards, even though the external interferences disappear, current leakage (i.e., a lock state) between the power supply terminal VDD and the ground terminal VSS may still exist due to positive feedback formed between the two triodes. This results in the latch-up effect.

This embodiment provides an integrated circuit latch-up test structure. In this test structure, electrical parameters of the latch-up effect of an integrated circuit corresponding to the integrated circuit latch-up test structure may be tested by adjusting at least one of the first distance, the second distance, and the third distance. In this way, the first distance, the second distance and the third distance in the integrated circuit corresponding to the integrated circuit latch-up test structure may be set by means of the electrical parameters of the latch-up effect and the first distance, the second distance, and the third distance. Thus, occurrence of the latch-up effect can be prevented in a working process of the integrated circuit, and a chip is prevented from being burned out due to the latch-up effect, such that reliability of the chip is improved.

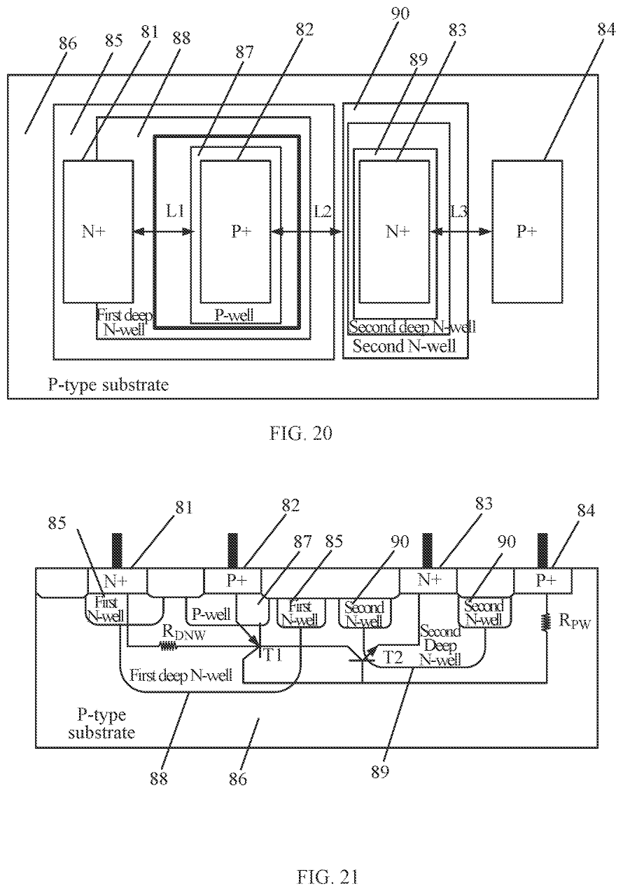

FIG. 20 is a vertical view of an integrated circuit latch-up test structure according to an embodiment of the present disclosure, and FIG. 21 is a sectional view of an integrated circuit latch-up test structure according to an embodiment of the present disclosure. With reference to FIG. 20 and FIG. 21, the integrated circuit latch-up test structure of this embodiment may include: a first N-type heavily doped region 81, a first P-type heavily doped region 82, a second N-type heavily doped region 83, and a second P-type heavily doped region 84.

The first N-type heavily doped region 81 is positioned in a first N-well 85, and the first N-well 85 is positioned on a P-type substrate 86. The first P-type heavily doped region 82 is positioned in a P-well 87, the P-well 87 is positioned in a first deep N-well 88, and the first deep N-well 88 is positioned in the first N-well 85. The second N-type heavily doped region 83 is positioned in a second deep N-well 89, the second deep N-well 89 is positioned in a second N-well 90, and the second N-well 90 is positioned on the P-type substrate 86. The second P-type heavily doped region 84 is positioned on the P-type substrate 86.

The first distance L1 is provided between the first N-type heavily doped region 81 and the first P-type heavily doped region 82, the second distance L2 is provided between the first P-type heavily doped region 82 and the second N-type heavily doped region 83, and the third distance L3 is provided between the second N-type heavily doped region 83 and the second P-type heavily doped region 84.

The test structure is configured to test the electrical parameters of the latch-up effect of the integrated circuit corresponding to the test structure by adjusting at least one of the first distance L1, the second distance L2, and the third distance L3.

Further, as shown in FIG. 21, the P-well 87, the first deep N-well 88 and the P-type substrate 86 constitute the first parasitic PNP transistor T1. The first deep N-well 88, the P-type substrate 86 and the second deep N-well 89 constitute the first parasitic NPN transistor T2.

The deep N-well 88 has a first parasitic resistor R_{DNW}, wherein a first terminal of the first parasitic resistor R_{DNW} is connected to the first N-type heavily doped region 81, and a second terminal of the first parasitic resistor R_{DNW} is connected to a base of the first parasitic PNP transistor T1.

The P-type substrate 86 has a second parasitic resistor R_{PW}, wherein a first terminal of the second parasitic resistor R_{PW} is connected to the second P-type heavily doped region 84, and a second terminal of the second parasitic resistor R_{PW} is connected to a base of the first parasitic NPN transistor T2 and a collector of the first parasitic PNP transistor T1.

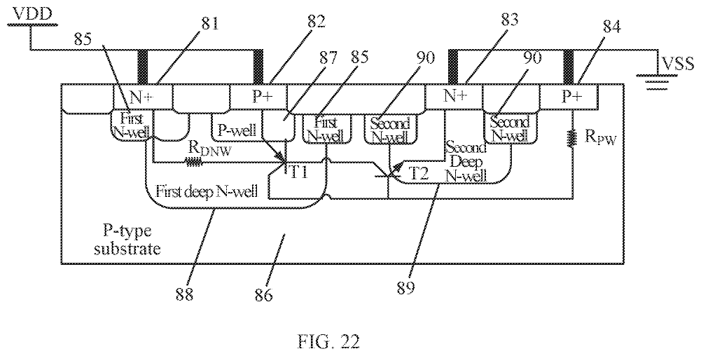

Test principles of the integrated circuit latch-up test structure as shown in FIG. 20 and FIG. 21 are described below with reference to FIG. 22. FIG. 22 is a schematic connection diagram of the integrated circuit latch-up test structures as shown in FIG. 20 and FIG. 21 when in test. As shown in FIG. 22, before the test, the first P-type heavily doped region 82 and the first N-type heavily doped region 81 are both connected to a power supply terminal VDD, and the second P-type heavily doped region 84 and the second N-type heavily doped region 83 are both connected to a ground terminal VSS. During the test, a voltage applied to the power supply terminal VDD gradually increases from 0V. For example, the voltage gradually increases from 0V to 5V. An electric current between the power supply terminal VDD and the ground terminal VSS is monitored. When the electric current between the power supply terminal VDD and the ground terminal VSS suddenly increases, it is determined that the latch-up effect occurs at this moment. The first distance L1, the second distance L2 and the third distance L3 are associated, to some degree, with the trigger voltage for triggering the latch-up effect, the holding voltage for holding the latch-up effect, the trigger current for triggering the latch-up effect, and the holding current for holding the latch-up effect. In some embodiments, a corresponding relationship table between the first distance L1, the second distance L2 and the third distance L3 and the trigger voltage for triggering the latch-up effect, the holding voltage for holding the latch-up effect, the trigger current for triggering the latch-up effect, and the holding current for holding the latch-up effect may be obtained. This table may serve as a basis for designing an integrated circuit corresponding to the integrated circuit latch-up test structure as shown in FIG. 20 and FIG. 21, to prevent the occurrence of the latch-up effect in a working process of the integrated circuit corresponding to the integrated circuit latch-up test structure. For example, the corresponding relationship table may be in the form of Table I above.

Principles of generation of the latch-up effect are described below. In some embodiments, T1 represents a vertical PNP transistor, a base thereof is an N-well, and a gain from the base to a collector may reach up to hundreds of times. T2 represents a side-type NPN transistor, a base thereof is a P-type substrate, and a gain from the base to a collector may reach up to dozens of times. R_{DNW} represents a parasitic resistor of the first deep N-well, and R_{PW} represents a parasitic resistor of the P-type substrate.

The above four components T1, T2, R_{DNW} and R_{PW} constitute a silicon controlled circuit. When there is no external interference or triggering, the two transistors are in an off state. A collector current comprises a reverse leakage current of C-B, and a current gain is very small. In this case, the latch-up effect does not occur. When the collector current of one of the two transistors suddenly increases to a certain value due to external interferences, this may be fed back to the other transistor, such that the two transistors are enabled due to triggering (generally, it is easier to trigger the PNP transistor), and thus a low-impedance path is formed between the power supply terminal VDD and the ground terminal VSS. Afterwards, even though the external interferences disappear, current leakage (i.e., a lock state) between the power supply terminal VDD and the ground terminal VSS may still exist due to positive feedback formed between the two triodes. This results in the latch-up effect.

This embodiment provides an integrated circuit latch-up test structure. In this test structure, electrical parameters of the latch-up effect of an integrated circuit corresponding to the integrated circuit latch-up test structure may be tested by adjusting at least one of the first distance, the second distance, and the third distance. In this way, the first distance, the second distance and the third distance in the integrated circuit corresponding to the integrated circuit latch-up test structure may be set by means of the electrical parameters of the latch-up effect and the first distance, the second distance, and the third distance. Thus, occurrence of the latch-up effect can be prevented in a working process of the integrated circuit, and a chip is prevented from being burned out due to the latch-up effect, such that reliability of the chip is improved.

Finally, it should be noted that the foregoing embodiments are merely intended for describing the technical solutions of the present disclosure, but not for limiting the present disclosure. Although the present disclosure is described in detail with reference to the foregoing embodiments, persons of ordinary skill in the art should understand that they may still make modifications to the technical solutions described in the foregoing embodiments or make equivalent replacements to some or all technical features thereof, which does not make corresponding technical solutions in essence depart from the scope of the technical solutions of the embodiments of the present disclosure.

What is claimed is:

1. An integrated circuit latch-up test structure, comprising:
a first P-type heavily doped region, a first N-type heavily doped region, a second P-type heavily doped region, and a second N-type heavily doped region;
wherein the first P-type heavily doped region and the first N-type heavily doped region are both positioned on a P-type substrate, the second P-type heavily doped region and the second N-type heavily doped region both being positioned in an N-well, and the N-well being positioned on the P-type substrate;
a first distance being provided between the first P-type heavily doped region and the first N-type heavily doped region, a second distance being provided between the first N-type heavily doped region and the second P-type heavily doped region, and a third distance being provided between the second P-type heavily doped region and the second N-type heavily doped region; and
the test structure being configured to test an electrical parameter of a latch-up effect of an integrated circuit corresponding to the test structure by adjusting at least one of the first distance, the second distance, and the third distance.

2. The integrated circuit latch-up test structure according to claim 1, wherein the N-well, the P-type substrate and the first N-type heavily doped region constitute a first parasitic NPN transistor; and
the second P-type heavily doped region, the N-well and the P-type substrate constitute a first parasitic PNP transistor.

3. The integrated circuit latch-up test structure according to claim 2, wherein the P-type substrate has a first parasitic resistor, a first terminal of the first parasitic resistor being connected to the first P-type heavily doped region, a second terminal of the first parasitic resistor being connected to a base of the first parasitic NPN transistor; and
the N-well has a second parasitic resistor, a first terminal of the second parasitic resistor being connected to the second N-type heavily doped region, and a second terminal of the second parasitic resistor being connected to a base of the first parasitic PNP transistor.

4. An integrated circuit latch-up test structure, comprising:
a first P-type heavily doped region, a first N-type heavily doped region, a second P-type heavily doped region, and a second N-type heavily doped region;
wherein the first P-type heavily doped region is positioned on a P-type substrate, the first N-type heavily doped region being positioned in a first N-well, the second P-type heavily doped region and the second N-type heavily doped region both being positioned in a second N-well, and the first N-well and the second N-well both being positioned on the P-type substrate;
a first distance being provided between the first P-type heavily doped region and the first N-type heavily doped region, a second distance being provided between the first N-type heavily doped region and the second P-type heavily doped region, and a third distance being provided between the second P-type heavily doped region and the second N-type heavily doped region; and
the test structure being configured to test an electrical parameter of a latch-up effect of an integrated circuit corresponding to the test structure by adjusting at least one of the first distance, the second distance, and the third distance.

5. The integrated circuit latch-up test structure according to claim 4, wherein the second N-well, the P-type substrate and the first N-type heavily doped region constitute a first parasitic NPN transistor; and
the second P-type heavily doped region, the second N-well and the P-type substrate constitute a first parasitic PNP transistor.

6. The integrated circuit latch-up test structure according to claim 5, wherein the P-type substrate has a first parasitic resistor, a first terminal of the first parasitic resistor being connected to the first P-type heavily doped region, a second terminal of the first parasitic resistor being connected to a base of the first parasitic NPN transistor; and
the second N-well has a second parasitic resistor, a first terminal of the second parasitic resistor being connected to the second N-type heavily doped region, and a second terminal of the second parasitic resistor being connected to a base of the first parasitic PNP transistor.

7. An integrated circuit latch-up test structure, comprising:
a first P-type heavily doped region, a first N-type heavily doped region, a second P-type heavily doped region, and a second N-type heavily doped region;
wherein the first P-type heavily doped region is positioned on a P-type substrate, the first N-type heavily doped region being positioned in a deep N-well, the deep N-well being positioned in a first N-well, the second P-type heavily doped region and the second N-type heavily doped region both being positioned in a second N-well, and the first N-well and the second N-well both being positioned on the P-type substrate;
a first distance being provided between the first P-type heavily doped region and the first N-type heavily doped region, a second distance being provided between the first N-type heavily doped region and the second P-type heavily doped region, and a third distance being provided between the second P-type heavily doped region and the second N-type heavily doped region; and
the test structure being configured to test an electrical parameter of a latch-up effect of an integrated circuit corresponding to the test structure by adjusting at least one of the first distance, the second distance, and the third distance.

8. The integrated circuit latch-up test structure according to claim 7, wherein the second N-well, the P-type substrate and the deep N-well constitute a first parasitic NPN transistor; and
the second P-type heavily doped region, the second N-well and the P-type substrate constitute a first parasitic PNP transistor.

9. The integrated circuit latch-up test structure according to claim 8, wherein the P-type substrate has a first parasitic resistor, a first terminal of the first parasitic resistor being connected to the first P-type heavily doped region, a second terminal of the first parasitic resistor being connected to an emitter of the first parasitic NPN transistor; and
the second N-well has a second parasitic resistor, a first terminal of the second parasitic resistor being connected to the second N-type heavily doped region, and a second terminal of the second parasitic resistor being connected to a base of the first parasitic PNP transistor.

10. An integrated circuit latch-up test structure, comprising:
a first N-type heavily doped region, a first P-type heavily doped region, a second N-type heavily doped region, and a second P-type heavily doped region;
wherein the first N-type heavily doped region and the first P-type heavily doped region are both positioned in a deep N-well, the deep N-well being positioned in an N-well, and the N-well being positioned on a P-type substrate;
the second N-type heavily doped region and the second P-type heavily doped region are both positioned in a P-well, the P-well being positioned in the deep N-well;
a first distance being provided between the first N-type heavily doped region and the first P-type heavily doped region, a second distance being provided between the first P-type heavily doped region and the second N-type heavily doped region, and a third distance being provided between the second N-type heavily doped region and the second P-type heavily doped region; and
the test structure being configured to test an electrical parameter of a latch-up effect of an integrated circuit corresponding to the test structure by adjusting at least one of the first distance, the second distance, and the third distance.

11. The integrated circuit latch-up test structure according to claim 10, wherein the first P-type heavily doped region, the deep N-well and the second P-type heavily doped region constitute a first parasitic PNP transistor; and
the first N-type heavily doped region, the P-type substrate and the deep N-well constitute a first parasitic NPN transistor.

12. The integrated circuit latch-up test structure according to claim 11, wherein the deep N-well has a first parasitic resistor, a first terminal of the first parasitic resistor being connected to the first N-type heavily doped region, and a second terminal of the first parasitic resistor being connected to a base of the first parasitic PNP transistor; and
the P-well has a second parasitic resistor, a first terminal of the second parasitic resistor being connected to the second P-type heavily doped region, and a second terminal of the second parasitic resistor being connected to a base of the first parasitic NPN transistor and a collector of the first parasitic PNP transistor.

13. An integrated circuit latch-up test structure, comprising:
a first N-type heavily doped region, a first P-type heavily doped region, a second N-type heavily doped region, and a second P-type heavily doped region;
wherein the first N-type heavily doped region is positioned in an N-well, the N-well being positioned on a P-type substrate;
the first P-type heavily doped region being positioned in a P-well, the P-well being positioned in a deep N-well, and the deep N-well being positioned in the N-well;
the second N-type heavily doped region and the second P-type heavily doped region both being positioned on the P-type substrate;
a first distance being provided between the first N-type heavily doped region and the first P-type heavily doped region, a second distance being provided between the first P-type heavily doped region and the second N-type heavily doped region, and a third distance being provided between the second N-type heavily doped region and the second P-type heavily doped region; and
the test structure being configured to test an electrical parameter of a latch-up effect of an integrated circuit corresponding to the test structure by adjusting at least one of the first distance, the second distance, and the third distance.

14. The integrated circuit latch-up test structure according to claim 13, wherein the P-well, the deep N-well and the P-type substrate constitute a first parasitic PNP transistor; and
the deep N-well, the P-type substrate and the second N-type heavily doped region constitute a first parasitic NPN transistor.

15. The integrated circuit latch-up test structure according to claim 14, wherein the deep N-well has a first parasitic resistor, a first terminal of the first parasitic resistor being connected to the first N-type heavily doped region, and a second terminal of the first parasitic resistor being connected to a base of the first parasitic PNP transistor; and
the P-type substrate has a second parasitic resistor, a first terminal of the second parasitic resistor being connected to the second P-type heavily doped region, and a second terminal of the second parasitic resistor being connected to a base of the first parasitic NPN transistor and a collector of the first parasitic PNP transistor.

16. An integrated circuit latch-up test structure, comprising:
a first N-type heavily doped region, a first P-type heavily doped region, a second N-type heavily doped region, and a second P-type heavily doped region;
wherein the first N-type heavily doped region is positioned in a first N-well, the first N-well being positioned on a P-type substrate;
the first P-type heavily doped region being positioned in a P-well, the P-well being positioned in a deep N-well, and the deep N-well being positioned in the first N-well;
the second N-type heavily doped region being positioned in a second N-well, the second N-well being positioned on the P-type substrate;
the second P-type heavily doped region being positioned on the P-type substrate;
a first distance being provided between the first N-type heavily doped region and the first P-type heavily doped region, a second distance being provided between the first P-type heavily doped region and the second N-type heavily doped region, and a third distance being provided between the second N-type heavily doped region and the second P-type heavily doped region; and
the test structure being configured to test an electrical parameter of a latch-up effect of an integrated circuit corresponding to the test structure by adjusting at least one of the first distance, the second distance, and the third distance.

17. The integrated circuit latch-up test structure according to claim 16, wherein the P-well, the deep N-well and the P-type substrate constitute a first parasitic PNP transistor; and
the deep N-well, the P-type substrate and the second N-well constitute a first parasitic NPN transistor.

18. The integrated circuit latch-up test structure according to claim 17, wherein the deep N-well has a first parasitic resistor, a first terminal of the first parasitic resistor being connected to the first N-type heavily doped region, and a second terminal of the first parasitic resistor being connected to a base of the first parasitic PNP transistor; and
the P-type substrate has a second parasitic resistor, a first terminal of the second parasitic resistor being connected to the second P-type heavily doped region, and a second terminal of the second parasitic resistor being connected to a base of the first parasitic NPN transistor and a collector of the first parasitic PNP transistor.

19. An integrated circuit latch-up test structure, comprising:
a first N-type heavily doped region, a first P-type heavily doped region, a second N-type heavily doped region, and a second P-type heavily doped region;
wherein the first N-type heavily doped region is positioned in a first N-well, the first N-well being positioned on a P-type substrate;
the first P-type heavily doped region being positioned in a P-well, the P-well being positioned in a first deep N-well, and the first deep N-well being positioned in the first N-well;
the second N-type heavily doped region being positioned in a second deep N-well, the second deep N-well being positioned in a second N-well, the second N-well being positioned on the P-type substrate;
the second P-type heavily doped region being positioned on the P-type substrate;
a first distance being provided between the first N-type heavily doped region and the first P-type heavily doped region, a second distance being provided between the first P-type heavily doped region and the second N-type heavily doped region, and a third distance being provided between the second N-type heavily doped region and the second P-type heavily doped region; and
the test structure being configured to test an electrical parameter of a latch-up effect of an integrated circuit corresponding to the test structure by adjusting at least one of the first distance, the second distance, and the third distance.

20. The integrated circuit latch-up test structure according to claim 19, wherein the P-well, the first deep N-well and the P-type substrate constitute a first parasitic PNP transistor; and
the first deep N-well, the P-type substrate and the second deep N-well constitute a first parasitic NPN transistor.
